(19) United States
(12) Patent Application Publication
(10) Pub. No.: US 2024/0162213 A1
(43) Pub. Date: May 16, 2024

(54) CHIP ON FILM PACKAGE AND DISPLAY APPARATUS INCLUDING THE SAME

(71) Applicant: SAMSUNG ELECTRONICS CO., LTD., Suwon-si (KR)

(72) Inventors: Yechung CHUNG, Suwon-si (KR); Woonbae KIM, Suwon-si (KR); Jeongkyu HA, Suwon-si (KR)

(21) Appl. No.: 18/376,467

(22) Filed: Oct. 4, 2023

(30) Foreign Application Priority Data
Nov. 15, 2022 (KR) 10-2022-0152739

(51) Int. Cl. H01L 25/18; H01L 23/552; H10K 59/90

(52) U.S. Cl. CPC H01L 25/18; H01L 23/552; H10K 59/90; H01L 23/5387

(57) ABSTRACT

A display apparatus includes a silicon substrate including a first surface and a second surface opposite thereto and including an opaque material, a display panel disposed on the first surface of the silicon substrate, a base film including a third surface and a fourth surface opposite thereto, the fourth surface having a portion facing the first surface of the silicon substrate, a display driving chip mounted on the base film, a connector disposed on a portion of the third surface of the base film, and a driving printed circuit board (PCB) electrically connected with the base film, wherein the silicon substrate corresponds to the base film in a one-to-one relationship, and a length of an edge of the base film overlapping the silicon substrate is about 90% of a length of an edge of the silicon substrate parallel to the edge of the base film.

### CROSS-REFERENCE TO RELATED APPLICATION

This application is based on and claims priority under 35 U.S.C. § 119 to Korean Patent Application No. 10-2022-0152739, filed on Nov. 15, 2022, in the Korean Intellectual Property Office, the disclosure of which is incorporated by reference herein in its entirety.

### BACKGROUND

### 1. Field

Embodiments relate to a chip on package and a display apparatus including the same, and more particularly, to a chip on package attached on a silicon substrate and a display apparatus including the chip on package.

### 2. Description of the Related Art

In chip on film (COF) packages, a semiconductor chip may be mounted on a base film, and the mounted semiconductor chip may be electrically connected with an external device through a conductive line and a conductive pad connected thereto, in the base film. Recently, as miniaturization of a bezel and thinning of a panel are more needed, the kind and number of semiconductor chips mounted on one COF package are progressively increasing.

### SUMMARY

Embodiments may provide a display apparatus where a size of a silicon substrate with an organic light emitting device mounted thereon is reduced.

Embodiments may provide a display apparatus where a signal is easily transferred between a display driving chip and a power management chip.

The object of the embodiments is not limited to the aforesaid, but other objects not described herein will be clearly understood by those of ordinary skill in the art from descriptions below.

According to embodiments, there is provided a display apparatus including a silicon substrate including a first surface and a second surface opposite thereto and including an opaque material, a display panel disposed on the first surface of the silicon substrate, a base film including a third surface and a fourth surface opposite thereto, the fourth surface having a portion facing the first surface of the silicon substrate, a display driving chip mounted on the base film, a connector disposed on a portion of the third surface of the base film, and a driving printed circuit board (PCB) electrically connected to the base film, wherein the silicon substrate corresponds to the base film in a one-to-one relationship, and a length of an edge of the base film overlapping the silicon substrate is about 90% of a length of an edge of the silicon substrate parallel to the edge of the base film.

According to embodiments, there is provided a display apparatus including a silicon substrate including a first surface and a second surface opposite thereto and including an opaque material, a display panel disposed on the first surface of the silicon substrate, a base film including a third surface and a fourth surface opposite thereto, the fourth surface having a portion facing the first surface of the silicon substrate, a plurality of semiconductor chips mounted on the base film, a connector disposed on a portion of the third surface of the base film, and a driving printed circuit board (PCB) electrically connected with the base film, wherein the silicon substrate corresponds to the base film in a one-to-one relationship.

According to embodiments, there is provided a display apparatus including a silicon substrate including a first surface and a second surface opposite thereto and including an opaque material, a display panel disposed on the first surface of the silicon substrate, a base film including a third surface and a fourth surface opposite thereto, the fourth surface having a portion facing the first surface of the silicon substrate, a plurality of semiconductor chips mounted on the base film, a first metal tape attached on the plurality of semiconductor chips, a second metal tape attached on a surface, which is opposite to a surface with the plurality of semiconductor chips mounted thereon, of the based film, a connector disposed on a portion of the third surface of the base film, and a driving printed circuit board (PCB) electrically connected with the base film, wherein the silicon substrate corresponds to the base film in a one-to-one relationship, a length of an edge of the base film overlapping the silicon substrate is about 90% of a length of an edge of the silicon substrate parallel to the edge of the base film, the plurality of semiconductor chips include a display driving chip and a power management integrated chip, a separation distance between the display driving chip and the display panel is less than a separation distance between the power management integrated chip and the display panel, and the power management integrated chip is disposed between the display driving chip and the connector.

### BRIEF DESCRIPTION OF THE DRAWINGS

Features will become apparent to those of skill in the art by describing in detail exemplary embodiments with reference to the attached drawings in which:

FIG. 1 is a plan view schematically illustrating a display apparatus according to an embodiment;

FIGS. 2 and 3 are plan views schematically illustrating a portion of a display apparatus according to an embodiment;

FIGS. 4 and 5 are side cross-sectional views schematically illustrating a display apparatus according to an embodiment;

FIG. 6 is a plan view schematically illustrating a display apparatus according to an embodiment;

FIGS. 7 to 9 are side cross-sectional views schematically illustrating a display apparatus according to an embodiment; and

FIGS. 10 to 12 are side cross-sectional views schematically illustrating a base film of a display apparatus according to an embodiment.

### DETAILED DESCRIPTION

Embodiments may be variously modified and may have various forms, and therefore, some embodiments are illustrated in the drawings and will be described in detail. However, this does not intend to limit embodiments to a specific form.

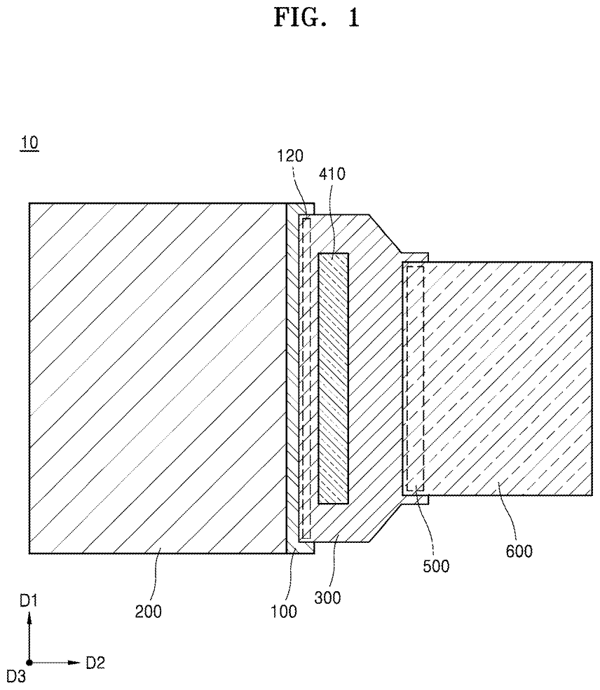

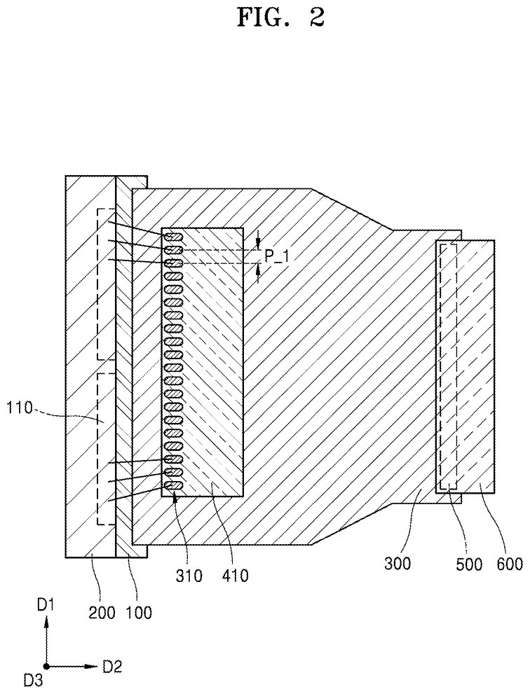

FIG. 1 is a plan view schematically illustrating a display apparatus 10 according to an embodiment. FIG. 2 is a plan view schematically illustrating a display apparatus according to an embodiment.

Referring to FIG. 1, the display apparatus 10 may include a silicon substrate 100, a display panel 200, a base film 300, a display driver chip 410, a connector 500, and a driving printed circuit board (PCB) 600.

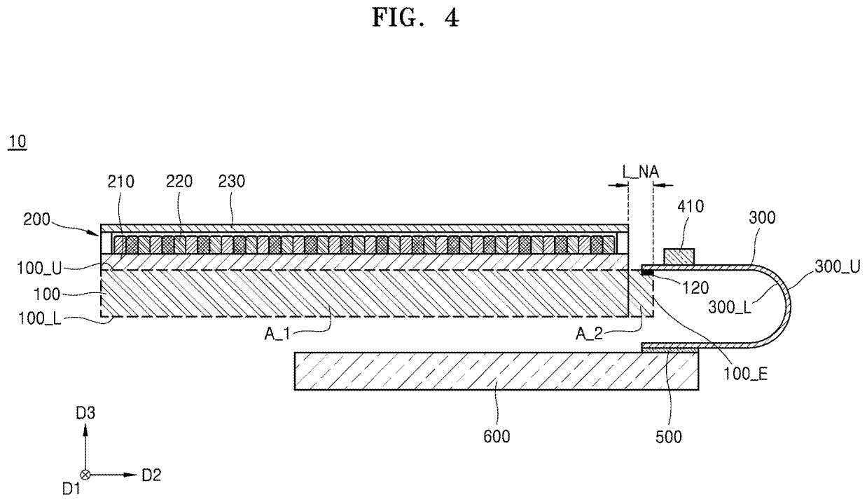

The silicon substrate 100 of the display apparatus 10 may include a first surface (100_U of FIG. 4) and a second surface (100_L of FIG. 4) opposite thereto. The silicon substrate 100 may be electrically connected with the display panel 200. The silicon substrate 100 may include an opaque material. For example, light emitted from the display panel 200 may not pass through the silicon substrate 100. In some embodiments, the silicon substrate 100 may include a panel connection wiring and a wiring via therein.

In some embodiments, a material of the silicon substrate 100 may include silicon (Si). Also, a material of the silicon substrate 100 may include a semiconductor element, such as germanium (Ge), or a compound semiconductor such as silicon carbide (SiC), gallium arsenide (GaAs), indium arsenide (InAs), or indium phosphide (InP).

The display panel 200 of the display apparatus 10 may be disposed on the first surface (100_U of FIG. 4) of the silicon substrate 100. The display panel 200 may be supplied with power through the silicon substrate 100 to emit light. The display panel 200 may include a plurality of organic light-emitting diodes (OLEDs). A structure of the display panel 200 will be described below with reference to FIG. 4.

In some embodiments, the plurality of OLEDs of the display panel 200 may be connected with a plurality of panel connection wirings corresponding thereto and may operate based on a signal provided by a semiconductor chip mounted on the base film 300. The plurality of OLEDs of the display panel 200 may respectively emit red (R) light, blue (B) light, and green (G) light, and various colors may be provided to a user, based on a combination of the R light, the G light, and the B light respectively emitted from the OLEDs.

The display apparatus 10 may include an OLED on silicon (OLEDOS). That is, the display apparatus 10 may include an OLEDOS where an OLED is mounted on the silicon substrate 100. In the OLEDOS, an OLED may be mounted on the silicon substrate 100, and a size of a pixel may be reduced compared to a display apparatus where an OLED is mounted on a glass substrate. Therefore, in the display apparatus 10 including the OLEDOS, because a size of each pixel is small, a pixel per inch (PPI) may increase, and thus, a high-resolution image may be provided to a user.

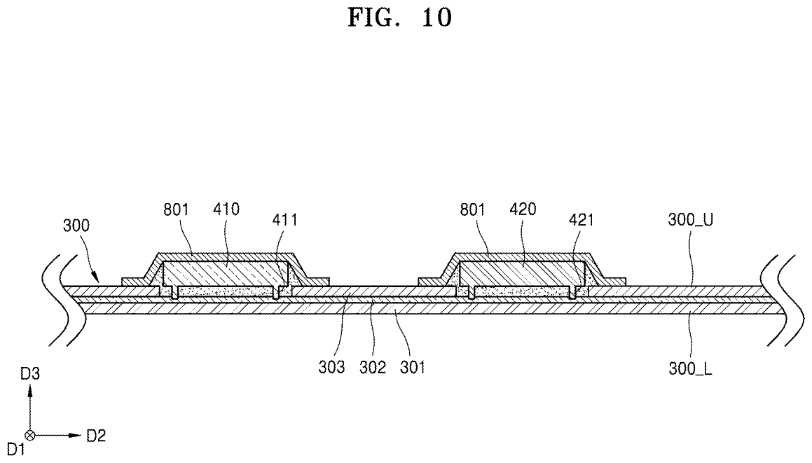

The base film 300 of the display apparatus 10 may include a third surface (300_L of FIG. 4) and a fourth surface (300_U of FIG. 4) opposite thereto. The display driver chip 410 may be provided on the third surface or the fourth surface of the base film 300. The base film 300 may include a wiring layer (302 of FIG. 10), and thus, may transfer or receive a signal to or from the display driver chip 410.

A portion of the fourth surface (300_L of FIG. 4) of the base film 300 may face the first surface (100_L of FIG. 4) of the silicon substrate 100. For example, a portion of the base film 300 may overlap the silicon substrate 100. In more detail, a portion of the base film 300 may be attached to the silicon substrate 100 by an anisotropic conductive layer 120. In some embodiments, the anisotropic conductive layer 120 may include an anisotropic conductive film or an anisotropic conductive paste. The anisotropic conductive layer 120 may have a structure where conductive particles are dispersed in an insulation adhesive layer. Also, the anisotropic conductive layer 120 may allow electricity to flow in only a direction toward an electrode in performing a connection and may have an anisotropic electrical characteristic where insulation is present in a direction between adjacent electrodes. When an adhesive is melted by applying heat and pressure to the anisotropic conductive layer 120, conductive particles may be present between corresponding electrodes (for example, on an output pad and a panel connection wiring) to conduct electricity, but an adhesive may be applied to provide insulation between adjacent electrodes.

The base film 300 may correspond to the silicon substrate 100 in a one-to-one relationship. That is, one base film 300 may be attached on each silicon substrate 100. In some embodiments, a width of the silicon substrate 100 may be substantially the same as a width of the base film 300. In other words, a length of a first edge of the base film 300 overlapping the silicon substrate 100 may be substantially the same as a length of a second edge of the silicon substrate 100 parallel to the first edge. In some embodiments, a length of the first edge of the base film 300 may be about 90% of a length of the second edge of the silicon substrate 100.

In some embodiments, the base film 300 may be electrically connected to the silicon substrate 100 at one end thereof and may be electrically connected with the driving PCB 600 at the other end thereof. In some embodiments, the base film 300 may be disposed between the silicon substrate 100 and the driving PCB 600.

The display driver chip (DDI) of the display apparatus 10 may be mounted on the base film 300. The DDI 410 may be used to drive the display panel 200. In some embodiments, the DDI 410 may generate an image signal by using a data signal transferred from a timing controller and may output the image signal to the display panel 200. In some embodiments, the DDI 410 may output a scan signal, including an on/off signal of a transistor, to the display panel 200.

In some embodiments, the DDI 410 may include a plurality of signal channels. The plurality of signal channels may be connected with a pad of the base film 300 and may transfer or receive a signal. In some embodiments, the DDI 410 may receive a signal from the driving PCB 600 through the plurality of signal channels. Also, the DDI 410 may transfer a signal to the silicon substrate 100 through the plurality of signal channels. A connection between the DDI 410 and the base film 300 will be described below with reference to FIG. 2.

In some embodiments, a structure where the DDI 410 is mounted on the base film 300 may be referred to as a chip on film (COF) package. That is, a COF package may be a package where a semiconductor chip is mounted on the base film 300. The display apparatus may be, for example, a display apparatus including a COF package.

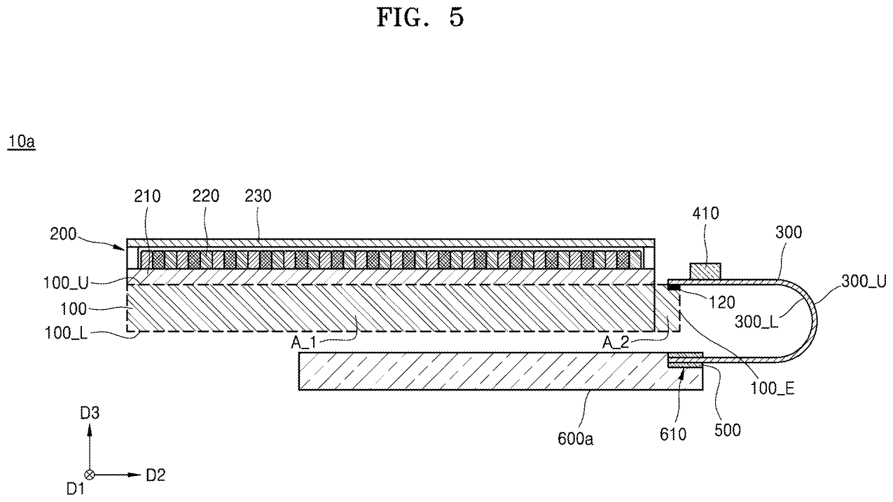

A connector 500 of the display apparatus 10 may be disposed on a portion of the third surface (300_U of FIG. 4) of the base film 300. In some embodiments, the connector 500 may be disposed on a surface that differs from the anisotropic conductive layer 120. That is, in a vertical viewpoint, the silicon substrate 100, the base film 300, and the driving PCB 600 may be sequentially stacked. The connector 500 may electrically connect the base film 300 with the driving PCB 600. In some embodiments, the connector 500 may have a structure where conductive particles are dispersed in an insulation adhesive layer. The connector 500 will be described below with reference to FIG. 5.

The driving PCB 600 of the display apparatus 10 may be electrically connected with the base film 300. In some embodiments, one or more driving circuit chips for simultaneously or sequentially applying power and a signal to the base film 300 or the DDI 410 may be mounted on the driving PCB 600. In some embodiments, a power management integrated chip (IC) (PMIC) for managing and supplying power to the DDI 410 and the display panel 200 may be mounted on the driving PCB 600.

In a general OLEDOS, a DDI may be mounted on a silicon substrate, and due to this, on a region of the silicon substrate where a display panel is not provided the silicon substrate may be larger, thereby creating an issue of productivity and economic efficiency. The display apparatus 10 according to the present embodiments may be the display apparatus 10 that includes the OLEDOS, and the DDI 410 may be mounted on the base film 300 instead of on the silicon substrate 100, thereby providing miniaturization of the silicon substrate 100. That is, the DDI 410 may not be mounted in a region of the silicon substrate 100 of the display apparatus 10, other than a region where the OLEDOS is mounted. Thus, a size of the silicon substrate 100 may be reduced.

FIG. 2 is a plan view schematically illustrating a display apparatus according to an embodiment.

In the following description of the display apparatus of FIG. 2, descriptions that are the same as or similar to the descriptions of the display apparatus 10 of FIG. 1 will not be repeated, and a difference therebetween will be described.

Referring to FIG. 2, a base film 300 may include a plurality of pads 310. Each of the plurality of pads 310 may be a conductive pad. The plurality of pads 310 may be electrically connected with a DDI 410 and may transfer power and a signal to the DDI 410. In some embodiments, the plurality of pads 310 may be connected with a signal channel of the DDI 410.

Hereinafter, a first direction D1 is a direction parallel to one end of a silicon substrate 100 contacting the base film 300, and a second direction D2 is a direction vertical to the first direction D1.

The plurality of pads 310 may be arranged apart from one another in the first direction D1. That is, the plurality of pads 310 may be arranged in one row. A separation distance P_1 between ones of the plurality of pads 310 may be changed based on the number of signal channels of the DDI 410. That is, the separation distance P_1 between the plurality of pads 310 may be equal to an interval between the signal channels of the DDI 410. In some embodiments, the separation distance P_1 between the plurality of pads 310 may be about 20 μm to about 30 μm.

In some embodiments, each pad of the plurality of pads 310 may be a portion of a wiring layer (302 of FIG. 10) of the base film 300, or may be a portion, plated with tin (Sb), gold (Au), nickel (Ni), or lead (Pb), of the wiring layer. In some embodiments, the plurality of pads 310 may be electrically connected with the wiring layer and may include a conductive material that is separately formed.

In some embodiments, the DDI 410 may transfer a signal to the silicon substrate 100 through the plurality of pads 310. In some embodiments, the plurality of pads 310 may be connected to a register 110 of the silicon substrate 100. For example, the register 110 may be a shift register. That is, a signal output from the DDI 410 may be connected with the register 110 of the silicon substrate 100 through the plurality of pads 310.

The display apparatus according to an embodiment may include a COF package which is the base film 300 with the DDI 410 mounted thereon. In the COF package, a semiconductor chip where an interval between signal channels is small may be mounted on the base film 300. That is, the base film 300 may include the plurality of pads 310 when a separation distance between adjacent pads 310 is small, and thus, a semiconductor chip where an interval between signal channels is small may be mounted on the base film 300. In a general display apparatus including an OLEDOS, a semiconductor chip where an interval between signal channels is small may be mounted on a silicon substrate by using a flexible PCB (FPCB). In the display apparatus according to an embodiment, the DDI 410 where an interval between signal channels is small may be removed from the silicon substrate 100 through a COF, and thus, a size of the silicon substrate 100 may be reduced.

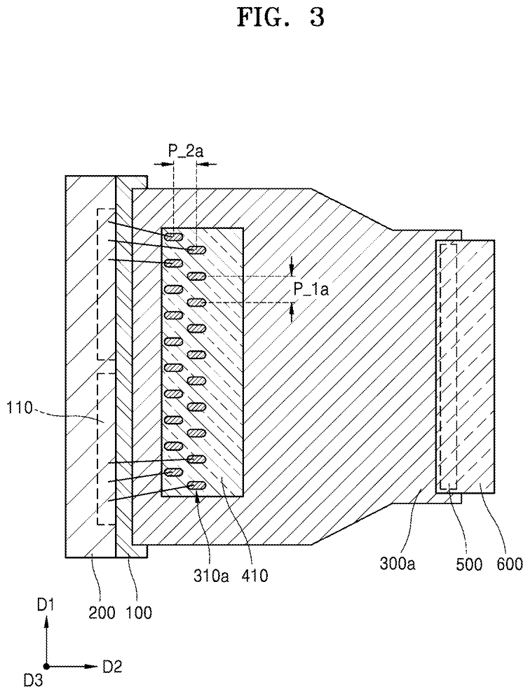

FIG. 3 is a plan view schematically illustrating a display apparatus according to an embodiment.

In the following description of the display apparatus of FIG. 3, descriptions that are the same as or similar to the descriptions of the display apparatus 10 of FIG. 1 sill not be repeated, and a difference therebetween will be described.

Referring to FIG. 3, a base film 300a may include a plurality of pads 310a. Each of the plurality of pads 310a may be a conductive pad. The plurality of pads 310a may be electrically connected with a DDI 410 and may transfer power and a signal to the DDI 410.

In some embodiments, the plurality of pads 310a may be arranged in a plurality of rows. That is, the plurality of pads 310a may be arranged in at least two rows. The plurality of pads 310a may be arranged apart from one another in a first direction D1. The plurality of rows may be arranged apart from one another in a second direction D2 vertical to the first direction D1. The plurality of pads 310a may be arranged so as to not overlap a different pad that may be disposed in an adjacent row in the second direction D2. That is, the plurality of pads 310a may be arranged in a plurality of rows apart from one another in the second direction D2, and a plurality of pads 310a arranged in each row may be apart from one another in the first direction D1 and may be disposed to be staggered with respect to pads 310a arranged in an adjacent row. In other words, the plurality of pads 310a may be arranged in a plurality of rows, and a plurality of pads 310a provided in an adjacent row may be arranged to be staggered with one another. In some embodiments, the plurality of pads 310a may be arranged in a stack shape.

In some embodiments, the plurality of pads 310a may be apart from one another by a first distance P_1a in the first direction D1 and may be apart from one another by a second distance P_2a in the second direction D2. The first distance P_1a may be about 20 μm to about 60 μm. The second distance P_2a may be about 10 μm to about 1,000 μm. Each of the first distance P_1a and the second distance P_2a is not limited to a numerical value described above and may be changed based on the number of signal channels of the DDI 410 and a size of the DDI 410.

In some embodiments, each of the plurality of pads 310a may be a portion of a wiring layer (302 of FIG. 10) of the base film 300, or may be a portion, plated with tin (Sb), gold (Au), nickel (Ni), or lead (Pb), of the wiring layer. In some embodiments, the plurality of pads 310a may be electrically connected with the wiring layer and may include a conductive material that is separately formed.

In some embodiments, the DDI 410 may transfer a signal to the silicon substrate 100 through the plurality of pads 310a. In some embodiments, the plurality of pads 310a may be connected with a register 110 of the silicon substrate 100. For example, the register 110 may be a shift register. That is, a signal output from the DDI 410 may be connected to the register 110 of the silicon substrate 100 through the plurality of pads 310a.

The display apparatus according to an embodiment may include a COF, which includes the base film 300a with the DDI 410 mounted thereon. The COF may include the plurality of pads 310a where a separation distance between adjacent pads 310a is small. When the plurality of pads 310a are arranged in a plurality of rows, the first distance P_1a between the plurality of pads 310a may increase. As the first distance P_1a between the plurality of pads 310a increases progressively, signal interference between signal channels of a DDI connected with a pad may decrease.

FIG. 4 is a side cross-sectional view schematically illustrating a display apparatus 10 according to an embodiment.

In the following description of the display apparatus 10 of FIG. 4, descriptions that are the same as or similar to the descriptions of the display apparatus 10 of FIG. 1 will not be repeated, and a difference therebetween will be described.

Referring to FIG. 4, a display panel 200 of the display apparatus 10 may include an emission layer 210 and a phosphor layer 220. The emission layer 210 of the display panel 200 may be disposed on a silicon substrate 100. The phosphor layer 220 may be disposed on the emission layer 210. The emission layer 210 may receive a signal and power from the silicon substrate 100 to emit light, and the emitted light may be changed to red light, blue light, or green light, based on changing of a wavelength through the phosphor layer 220.

In some embodiments, the emission layer 210 may include a conductive type semiconductor layer and an active layer. When power is supplied to the conductive type semiconductor layer, light may be emitted from the active layer. In some embodiments, the active layer may have a multiple quantum well (MQW) structure where a quantum well layer and a quantum barrier layer are alternately stacked. In some embodiments, the emission layer 210 may include a GaN layer, an AlGaN layer, an InGaN layer, and an InAlGaN layer.

In some embodiments, the phosphor layer 220 may include resin in which phosphors are dispersed or a film including a phosphor. For example, the phosphor layer 220 may include a phosphor film in which phosphor particles are uniformly dispersed at a certain concentration. The phosphor particles may be a wavelength conversion material that changes a wavelength of light emitted from the active layer. To enhance a density of phosphor particles and improve color uniformity, the phosphor layer 220 may include two or more kinds of phosphor particles having different size distributions.

In some embodiments, the display panel 200 may further include a substrate 230 that is on the phosphor layer 220 and may include a transparent material. A wavelength of light emitted from the emission layer 210 may be changed through the phosphor layer 220, and the light may pass through the substrate 230 including a transparent material and the light may be provided to a user. In some embodiments, the substrate 230 including a transparent material may be a glass substrate. The substrate 230 including a transparent material may prevent the phosphor layer 220 or the emission layer 210 from being polluted or damaged by the outside.

In some embodiments, the substrate 230 including a transparent material may be disposed on the display panel 200. The silicon substrate 100 may be disposed under the display panel 200. The display panel 200 may emit light upward and may receive power and a signal from the silicon substrate 100 thereunder.

A base film 300 of the display apparatus 10 may be a flexible film including a polyimide, which is a material having excellent durability and coefficient of thermal expansion. A material of the base film 300 is not limited thereto. For example, the base film 300 may include synthetic resin such as epoxy-based resin, acryl, polyether nitrile, polyether sulfone, polyethylene terephthalate, or polyethylene naphthalate.

In some embodiments, one end of the base film 300 may be disposed on the silicon substrate 100, and the other end thereof may be disposed on a driving PCB 600. The base film 300 may be bent and fixed to a second surface 100_L of the silicon substrate 100. Therefore, the driving PCB 600 disposed on the other end of the base film 300 may be apart from the second surface 100_L of the silicon substrate 100 with the base film 300 therebetween. In other words, the other end of the base film 300 may be bent to the second surface 100_L of the silicon substrate 100, and the driving PCB 600 may face the second surface 100_L of the silicon substrate 100.

In some embodiments, a connector 500 of the display apparatus 10 may be attached on one surface of the driving PCB 600. The connector 500 may be disposed on the base film 300 and may be attached on the driving PCB 600. That is, the connector 500 may electrically connect the base film 300 with the driving PCB 600. In some embodiments, the connector 500 may have a structure where conductive particles are dispersed in an insulation adhesive layer. The connector 500 may be attached on the one surface of the driving PCB 600 facing the second surface 100_L of the silicon substrate 100.

The silicon substrate 100 of the display apparatus 10 may be divided into an emission region A_1 and a non-emission region A_2. The emission region A_1 may be a region where the display panel 200 is disposed on the silicon substrate 100, and the non-emission region A_2 may be a region where the display panel 200 is not disposed on the silicon substrate 100. That is, the non-emission region A_2 may be a region up to an end portion of the silicon substrate 100 from an end portion of the display panel 200.

In some embodiments, an area of the non-emission region A_2 may be about 5% to about 10% of an area of the emission region A_1. In other words, a length of the non-emission region A_2 in a second direction D2 may be about 5% to about 10% of a length of the emission region A_1 in the second direction D2.

In some embodiments, a first end portion 100_E of the silicon substrate 100 may be disposed under the base film 300. That is, an end portion, disposed in a region contacting the silicon substrate 100, of the base film 300 may be a first end portion 100_E. A minimum separation distance between the display panel 200 and the first end portion 100_E may be a first length L_NA. In other words, a distance between the first end portion 100_E and an end portion of the display panel 200 closest to the first end portion 100_E may be the first length L_NA. In some embodiments, the first length L_NA may be about 0.5 nm to about 1.5 mm. In some embodiments, a separate semiconductor chip may be mounted between the display panel 200 and the first end portion 100_E. In some embodiments, the DDI 410 may not be mounted between the display panel 200 and the first end portion 100_E.

In the display apparatus 10 according to an embodiment, the DDI 410 may be mounted on the base film 300, and thus, the non-emission region A_2 may be reduced. That is, the non-emission region A_2 of the silicon substrate 100 may decrease, and thus, a size of the silicon substrate 100 may be reduced. When a size of the silicon substrate 100 is reduced, the productivity and economic efficiency of the silicon substrate 100 may be enhanced. In the display apparatus 10 according to an embodiment, the driving PCB 600 may be disposed to face the silicon substrate 100 by using a flexible film. The display apparatus 10 may be decreased in size, and thus, may be suitably used in an augmented reality (AR) device or a virtual reality (VR) device.

FIG. 5 is a side cross-sectional view schematically illustrating a display apparatus 10a according to an embodiment.

In the following description of the display apparatus 10a of FIG. 5, descriptions which are the same as or similar to the descriptions of the display apparatus 10 of FIG. 4 will not be repeated, and a difference therebetween will be described.

Referring to FIG. 5, a driving PCB 600a may include a hole 610, which may be formed in one surface thereof. The hole 610 may be provided to be attached/detached on/from a connector 500. That is, by connecting the connector 500 to the hole 610, the driving PCB 600a may be electrically connected with the base film 300.

In some embodiments, the driving PCB 600a may include a hole 610 that is formed an upper surface or a lower surface thereof. A recess may be disposed in a sidewall configuring the hole 610. The connector 500 may be fixed to the recess. That is, the connector 500 may be attachable or detachable to or in a groove through the recess. An electrical connection between the base film 300 and the driving PCB 600a may be easily performed through the driving PCB 600a including the hole 610.

In some embodiments, the connector 500 may be disposed on a third surface 300_U and a fourth surface 300_L of the base film 300. That is, the connector 500 may surround both surfaces of the base film 300. The driving PCB 600a may include a hole 610 that is formed in a side surface thereof. When the connector 500 is attached to the hole 610 of the driving PCB 600a, the connector 500 may be disposed in the driving PCB 600a. In some embodiments, when the connector 500 is disposed on the third surface 300_U and the fourth surface 300_L of the base film 300, an area where the connector 500 contacts the driving PCB 600a may increase.

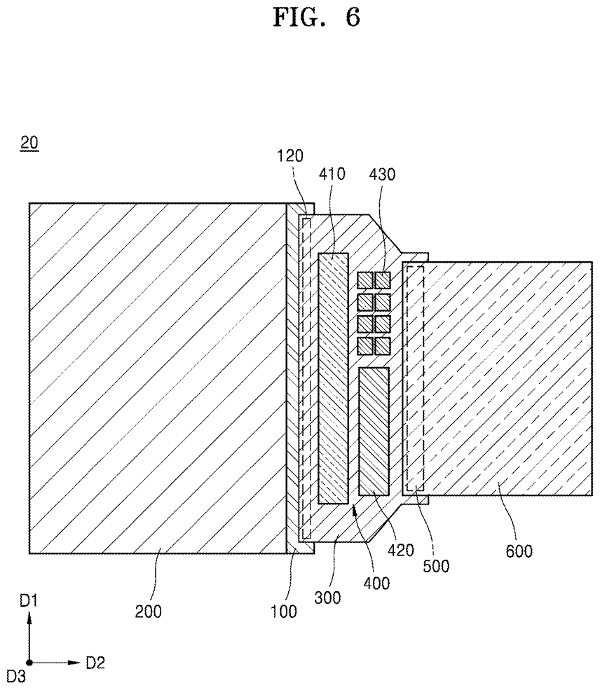

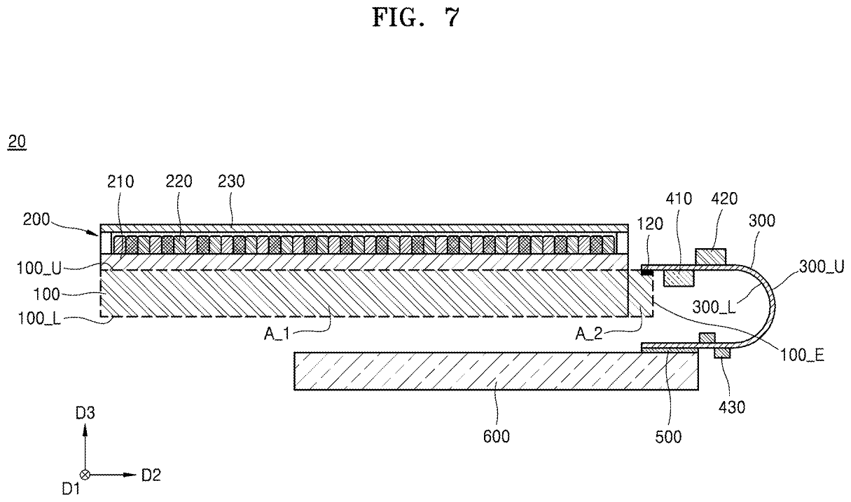

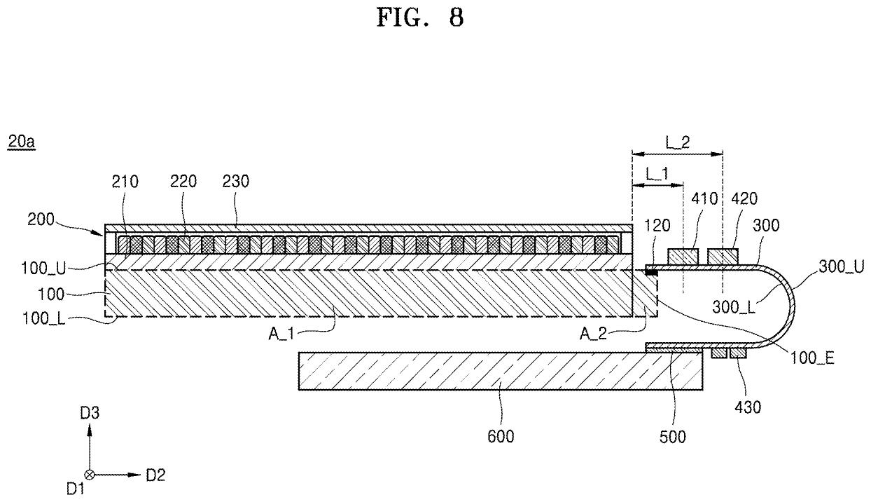

FIG. 6 is a plan view schematically illustrating a display apparatus 20 according to an embodiment. FIGS. 7 and 8 are side cross-sectional views schematically illustrating display apparatuses 20 and 20a according to an embodiment.

In the following description of the display apparatuses 20 and 20a of FIGS. 6 to 8, descriptions which are the same as or similar to the descriptions of the display apparatus 10 of FIG. 1 will not be repeated, and a difference therebetween will be described.

Referring to FIGS. 6 to 8, the display apparatuses 20 and 20a may each include a silicon substrate 100, a display panel 200, a base film 300, a plurality of semiconductor chips 400, a connector 500, and a driving PCB 600. The silicon substrate 100, the display panel 200, the connector 500, and the driving PCB 600 of the display apparatus 20 of FIG. 6 may include the silicon substrate 100, the display panel 200, and the driving PCB 600 of the display apparatus 10 of FIG. 1 described above.

The plurality of semiconductor chips 400 of each of the display apparatuses 20 and 20a may be mounted on the base film 300. In some embodiments, the plurality of semiconductor chips 400 may be disposed on a third surface 300_U or a fourth surface 300_L of the base film 300. In some embodiments, some of the plurality of semiconductor chips 400 may be mounted on the third surface 300_U of the base film 300. The other of the plurality of semiconductor chips 400 may be mounted on the fourth surface 300_L of the base film 300. That is, each of the plurality of semiconductor chips 400 may be disposed on one surface of the third surface 300_U and the fourth surface 300_L of the base film 300. In some embodiments, a DDI 410 may be mounted on the fourth surface 300_L of the base film 300, and a PMIC 420 may be disposed on the third surface 300_U of the base film 300. The plurality of semiconductor chips 400 may be disposed on both surfaces of the base film 300, and thus, a size of the base film 300 may be reduced.

In some embodiments, the plurality of semiconductor chips 400 of each of the display apparatuses 20 and 20a may include the DDI 410, the PMIC 420, and a passive device 430. In some embodiments, the DDI 410 may generate an image signal by using a data signal transferred from a timing controller and may output the image signal to the display panel 200. In some embodiments, the DDI 410 may output a scan signal, including an on/off signal of a transistor, to the display panel 200. In some embodiments, the PMIC 420 may supply power to the DDI 410 or the display panel 200. In some embodiments, the passive device 430 may be connected with the DDI 410.

In some embodiments, the PMIC 420 and the passive device 430 may be disposed between the DDI 410 and the connector 500. That is, the connector 500 may be apart from the DDI 410 with the PMIC 420 and the passive device 430 therebetween. In some embodiments, the DDI 410, the PMIC 420, and the connector 500 may be apart from the silicon substrate 100 in a second direction D2 and may be sequentially arranged on the base film 300. In other words, the PMIC 420 may be disposed closer to the DDI 410 than the driving PCB 600.

In some embodiments, a separation distance between the display panel 200 and the DDI 410 may be a first separation distance L_1, and a separation distance between the display panel 200 and the PMIC 420 may be a second separation distance L_2. The first separation distance L_1 may be less than the second separation distance L_2. That is, the DDI 410 may be disposed closer to the display panel 200 than the PMIC 420.

In the display apparatus 20 according to an embodiment, the DDI 410, the PMIC 420, and the passive device 430 may be mounted on the base film 300. The base film 300 may include a plurality of pads where a separation distance between adjacent pads is small, and a semiconductor chip (for example, the DDI 410 and the PMIC 420) where a pitch is small may be mounted on the base film 300. In the display apparatus 20 according to an embodiment, the DDI 410 may be disposed closer to the display panel 200 than a different semiconductor chip, and thus, reliability may be enhanced in transferring a signal to the silicon substrate 100.

In a general OLEDOS, the PMIC 420 may be mounted on the driving PCB 600, but in the display apparatus 20a according to an embodiment, the PMIC 420 may be mounted on the base film 300, whereby a separation distance between the DDI 410 and the PMIC 420 may be reduced. When the separation distance between the DDI 410 and the PMIC 420 is reduced, the reliability of signal transfer between the DDI 410 and the PMIC 420 may be enhanced.

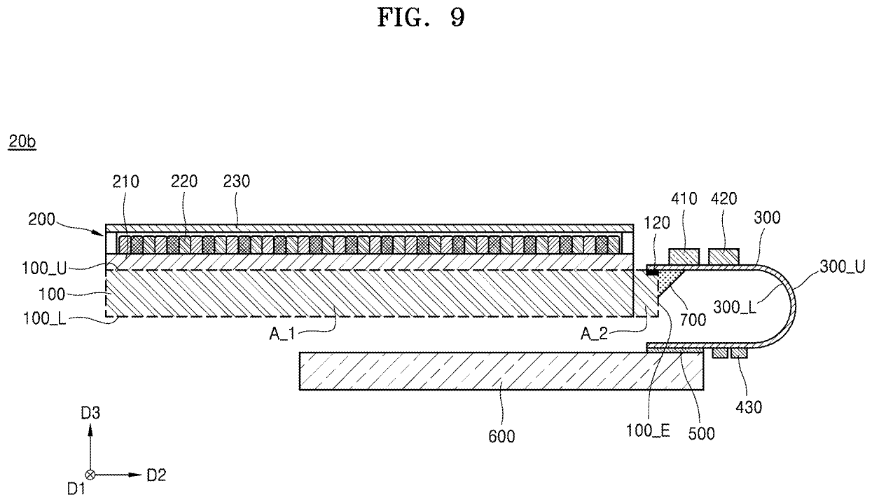

FIG. 9 is a side cross-sectional view schematically illustrating a display apparatus 20b according to an embodiment.

In the following description of the display apparatus 20b of FIG. 9, descriptions that are the same as or similar to the descriptions of the display apparatus 20a of FIG. 8 will not be repeated, and a difference therebetween will be described.

Referring to FIG. 9, the display apparatus 20b may further include a supporter 700. The supporter 700 may be disposed at a portion where a base film 300 contacts a silicon substrate 100. In other words, the supporter 700 may be disposed at a first end portion 100_E of the silicon substrate 100 disposed under the base film 300. The supporter 700 may be disposed on a side surface of the silicon substrate 100 and may be disposed on a fourth surface 300_L of the base film 300.

In an embodiment, the supporter 700 may contact the first end portion 100_E of the silicon substrate 100 and may contact the fourth surface 300_L of the base film 300. An area that contacts the base film 300 of the supporter 700 may be wide., Thus, when the base film 300 is bent, an area of the supporter 700 to which a force is applied may increase. The base film 300 may be a flexible film and may be bent to a second surface 100_L of the silicon substrate 100. An area where the silicon substrate 100 contacts the base film 300 may be small, and thus, an area of the base film 300 to which a force is applied may be small. A case where the base film 300 is damaged by the silicon substrate 100 could occur in a portion where the base film 300 contacts the silicon substrate 100. The supporter 700 may prevent the base film 300 from being damaged by the first end portion 100_E of the silicon substrate 100.

FIGS. 10 to 12 are side cross-sectional views schematically illustrating a base film of a display apparatus according to an embodiment.

The base film 300 described above with reference to FIG. 1 will be described below in detail with reference to FIGS. 10 to 12.

Referring to FIG. 10, a base film 300 of a display apparatus (10 of FIG. 1) according to an embodiment may include a flexible layer 301, a wiring layer 302, and a passivation layer 303. The wiring layer 302 may be disposed on the flexible layer 301, and the passivation layer 303 may be disposed on the wiring layer 302. In FIG. 10, a case is illustrated where the wiring layer 302 and the passivation layer 303 are disposed on the flexible layer 301 however, in some non-limiting implementations, a first wiring layer and a second passivation layer may be disposed on the flexible layer 301, and a second wiring layer and the second passivation layer may be disposed under the flexible layer 301.

In some embodiments, the flexible layer 301 may include synthetic resin such as polyimide, epoxy-based resin, acryl, polyether nitrile, polyether sulfone, polyethylene terephthalate, or polyethylene naphthalate.

In some embodiments, the wiring layer 302 may include an aluminum foil or a copper foil. A plurality of semiconductor chips may be connected to the wiring layer 302 and may transfer or receive a signal and power. In some embodiments, the wiring layer 302 may be electrically connected to the plurality of semiconductor chips through wiring vias 411 and 421. In detail, the wiring layer 302 may be exposed by forming a trench in a portion on which each of a plurality of semiconductor chips 410 and 420 is mounted. Then, the plurality of semiconductor chips 410 and 420 may be mounted by forming the wiring vias 411 and 421.

In some embodiments, the passivation layer 303 may protect the wiring layer 302 from external physical and/or chemical damage. The passivation layer 303 may include a solder resist or a dry film resist. Also, the passivation layer 303 may include a general insulation layer including silicon oxide or silicon nitride.

The display apparatus may include a first metal tape 801. The first metal tape 801 may be attached onto the plurality of semiconductor chips 410 and 420. In some embodiments, the plurality of semiconductor chips 410 and 420 may be disposed on a third surface 300_U of the base film 300, and the first metal tape 801 may be disposed on the passivation layer 303. That is, the first metal tape 801 may be attached on an upper surface of each of the plurality of semiconductor chips 410 and 420. The first metal tape 801 may surround a portion of each of the upper surface and a side surface of each of the plurality of semiconductor chips 410 and 420. In some embodiments, the first metal tape 801 may include a material that is high in thermal conductivity.

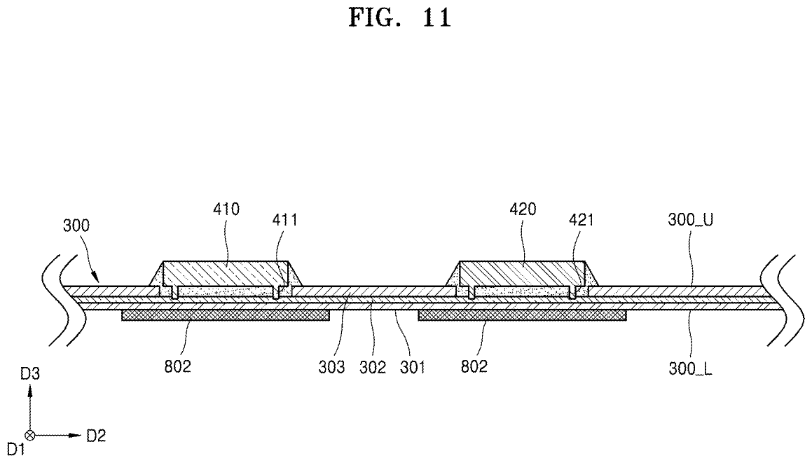

Referring to FIG. 11, the display apparatus may further include a second metal tape 802. The second metal tape 802 may be attached on a surface of a base film 300 that is opposite to a surface having a plurality of semiconductor chips 410 and 420 mounted thereon, of the base film 300. For example, when the plurality of semiconductor chips 410 and 420 are mounted on a third surface 300_U of the base film 300, the second metal tape 802 may be attached on a fourth surface 300_L, which is opposite to the third surface 300_U of the base film 300. The second metal tape 802 may be spaced apart from a corresponding semiconductor chip in a third direction D3 with the base film 300 therebetween and may be attached onto the base film 300. In some embodiments, the second metal tape 802 may include a material that is high in thermal conductivity. In FIG. 11, it is described that the second metal tape 802 is attached on the fourth surface 300_L, but embodiments are not limited thereto and the second metal tape 802 may be attached on the third surface 300_U or the fourth surface 300_L.

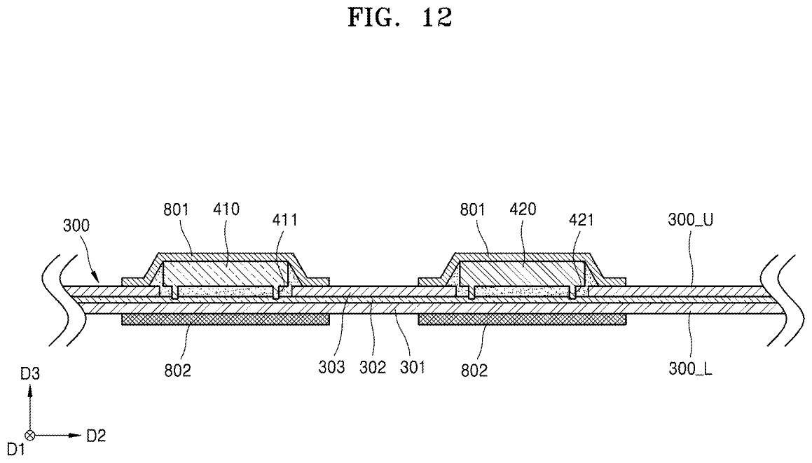

Referring to FIG. 12, the display apparatus may further include a first metal tape 801 and a second metal tape 802. The first metal tape 801 may be attached to a plurality of semiconductor chips 410 and 420, and the second metal tape 802 may be attached to a surface opposite to a surface having the plurality of semiconductor chips 410 and 420 mounted thereon. That is, the second metal tape 802 may be spaced apart from the first metal tape 801 in a third direction D3 with a base film 300 and a corresponding semiconductor chip therebetween. In some embodiments, when a DDI 410 is mounted on a third surface 300_U of the base film 300, the first metal tape 801 may be attached onto the DDI 410, and the second metal tape 802 may be attached onto a fourth surface 300_L of the base film 300.

The first metal tape 801 and the second metal tape 802 of the display apparatus according to an embodiment may be attached onto the base film 300. Heat could occur when a semiconductor chip is being driven. The first metal tape 801 and the second metal tape 802 may be high in thermal conductivity. Thus, it may be easy to dissipate the heat that may be generated in the semiconductor chip to the outside. An area for dissipating heat through the first metal tape 801 and the second metal tape 802 may increase, and thus, it may be easy to dissipate heat occurring in a semiconductor chip, to the outside. A peripheral electric wave, if present, could interfere with a semiconductor chip. however, the first metal tape 801 and the second metal tape 802 may prevent an electric wave from interfering with a semiconductor chip. Accordingly, the first metal tape 801 and the second metal tape 802 may prevent the occurrence of static electricity.

By way of summation and review, Embodiments may provide a display apparatus where a signal is easily transferred between a display driving chip and a power management chip.

Embodiments have been described by using the terms described herein, but this has been merely used for describing the embodiments and has not been used for limiting a meaning or limiting the scope of the embodiments defined in the following claims. Accordingly, the spirit and scope of the embodiments may be defined based on the spirit and scope of the following claims.

Example embodiments have been disclosed herein, and although specific terms are employed, they are used and are to be interpreted in a generic and descriptive sense only and not for purpose of limitation. Accordingly, it will be understood by those of skill in the art that various changes in form and details may be made without departing from the spirit and scope of the present invention as set forth in the following claims.

What is claimed is:

1. A display apparatus, comprising:
a silicon substrate including a first surface and a second surface opposite thereto and including an opaque material;
a display panel disposed on the first surface of the silicon substrate;
a base film including a third surface and a fourth surface opposite thereto, the fourth surface having a portion facing the first surface of the silicon substrate;
a display driving chip mounted on the base film;
a connector disposed on a portion of the third surface of the base film; and
a driving printed circuit board (PCB) electrically connected with the base film,
wherein:
the silicon substrate corresponds to the base film in a one-to-one relationship, and
a length of an edge of the base film overlapping the silicon substrate is about 90% of a length of an edge of the silicon substrate parallel to the edge of the base film.

2. The display apparatus as claimed in claim 1, further comprising a substrate including a transparent material, the substrate being disposed on the display panel,
wherein the silicon substrate is disposed under the display panel.

3. The display apparatus as claimed in claim 1, wherein a direction parallel to one end of the silicon substrate contacting the base film is a first direction,
the base film includes a plurality of pads,
the plurality of pads are connected with a signal channel of the display driving chip, and
the plurality of pads are arranged in one row in the first direction.

4. The display apparatus as claimed in claim 1, wherein the base film includes a plurality of pads arranged in a plurality of rows,
a direction parallel to one end of the silicon substrate contacting the base film is a first direction,
the plurality of pads are arranged apart from one another in the first direction in a same row,
the plurality of rows are apart from one another in a second direction vertical to the first direction, and
the plurality of pads do not overlap a plurality of pads, arranged in an adjacent row, in the second direction.

5. The display apparatus as claimed in claim 1, wherein the base film includes a flexible film.

6. The display apparatus as claimed in claim 5, wherein one end of the base film is disposed on the silicon substrate, and an other end thereof is disposed on the driving PCB,
the base film is bent and fixed to the second surface of the silicon substrate, and
the driving PCB is apart from the second surface of the silicon substrate with the base film therebetween.

7. The display apparatus as claimed in claim 6, wherein the connector is attached onto one surface of the driving PCB.

8. The display apparatus as claimed in claim 6, further comprising a hole formed in one end of the driving PCB and attachable or detachable onto or from the connector,
wherein the connector is attached on the hole and configured to connect the driving PCB with the base film.

9. The display apparatus as claimed in claim 1, wherein:
the first surface of the silicon substrate is divided into an emission region and a non-emission region,
the emission region is a region where the display panel overlaps the silicon substrate,
the non-emission region is a region up to an end portion of the silicon substrate from an end portion of the display panel, and an area occupied by the non-emission region is about 5% to about 10% of an area occupied by the emission region.

10. The display apparatus as claimed in claim 1, wherein:
at least a portion of the fourth surface of the base film contacts a first end portion of the silicon substrate, and a minimum separation distance between the display panel and the first end portion of the silicon substrate is about 0.5 mm to about 1.5 mm.

11. A display apparatus comprising:
a silicon substrate including a first surface and a second surface opposite thereto and including an opaque material;
a display panel disposed on the first surface of the silicon substrate;
a base film including a third surface and a fourth surface opposite thereto, the fourth surface having a portion facing the first surface of the silicon substrate;
a plurality of semiconductor chips mounted on the base film;
a connector disposed on a portion of the third surface of the base film; and
a driving printed circuit board (PCB) electrically connected with the base film,
wherein the silicon substrate corresponds to the base film in a one-to-one relationship.

12. The display apparatus as claimed in claim 11, wherein some of the plurality of semiconductor chips are mounted on the third surface of the base film, and
the other of the plurality of semiconductor chips are mounted on the fourth surface of the base film.

13. The display apparatus as claimed in claim 11, wherein the plurality of semiconductor chips include a display driving chip and a power management integrated chip.

14. The display apparatus as claimed in claim 13, wherein a separation distance between the display driving chip and the display panel is less than a separation distance between the power management integrated chip and the display panel.

15. The display apparatus as claimed in claim 13, further comprising a passive device mounted on the base film,
wherein the passive device and the power management integrated chip are disposed between the display driving chip and the connector.

16. The display apparatus as claimed in claim 11, further comprising a first metal tape attached on the plurality of semiconductor chips and configured to perform a heat dissipation function and a shielding function.

17. The display apparatus as claimed in claim 16, further comprising a second metal tape attached on a surface that is opposite to a surface of the base film having the plurality of semiconductor chips mounted thereon and configured to perform a heat dissipation function and a shielding function,
wherein the second metal tape is apart from the first metal tape with the base film and the plurality of semiconductor chips therebetween.

18. The display apparatus as claimed in claim 11, further comprising a second metal tape attached on a surface of the base film that is opposite to a surface with the plurality of semiconductor chips mounted thereon, and configured to perform a heat dissipation function and a shielding function.

19. The display apparatus as claimed in claim 11, further comprising a supporter disposed at a portion where the base film contacts the silicon substrate.

20. A display apparatus comprising:
a silicon substrate including a first surface and a second surface opposite thereto and including an opaque material;
a display panel disposed on the first surface of the silicon substrate;
a base film including a third surface and a fourth surface opposite thereto, the fourth surface having a portion facing the first surface of the silicon substrate;
a plurality of semiconductor chips mounted on the base film;
a first metal tape attached to the plurality of semiconductor chips;
a second metal tape attached onto a surface that is opposite to a surface of the base film having the plurality of semiconductor chips mounted thereon;
a connector disposed on a portion of the third surface of the base film; and
a driving printed circuit board (PCB) electrically connected to the base film,
wherein:
the silicon substrate corresponds to the base film in a one-to-one relationship,
a length of an edge of the base film overlapping the silicon substrate is about 90% of a length of an edge of the silicon substrate parallel to the edge of the base film,
the plurality of semiconductor chips includes a display driving chip and a power management integrated chip,
a separation distance between the display driving chip and the display panel is less than a separation distance between the power management integrated chip and the display panel, and
the power management integrated chip is disposed between the display driving chip and the connector.
